(19) United States
(12) Patent Application Publication
(10) Pub. No.: US 2026/0101759 A1
(43) Pub. Date: Apr. 9, 2026

(54) RADIATION-HARDENED SEMICONDUCTOR SYSTEMS

(71) Applicant: Micron Technology, Inc., Boise, ID (US)

(72) Inventors: Chong Leong Gan, Taichung (TW); Chen Yu Huang, Taichung (TW)

(21) Appl. No.: 19/351,492

(22) Filed: Oct. 7, 2025

Related U.S. Application Data
(60) Provisional application No. 63/704,996, filed on Oct. 8, 2024.

(51) Int. Cl. H01L 23/552; H01L 21/50; H01L 25/18; H10B 80/00; H10D 80/30

(52) U.S. Cl. CPC H10W 42/20; H10W 95/00; H10B 80/00; H10D 80/30; H10W 90/00

(57) ABSTRACT

Methods, systems, and devices for radiation hardening for semiconductor systems are described. Shielding materials may be used to protect components of a semiconductor system from incident radiation. In some examples, the shielding materials may include a combination of film materials, such as organic polymer films, and radiation shielding materials, such as boron compounds. The shielding layers can be arranged in various configurations, including multilayer, single layer, or filler-embedded configurations, which may balance film flexibility and radiation protection. By strategically placing these shielding layers on components of a semiconductor system, the system may effectively attenuate radiation incidence on circuitry of the semiconductor system, thereby reducing the likelihood of radiation-induced errors and enhancing the overall reliability of the semiconductor system.

### CROSS REFERENCE

The present Application for Patent claims priority to U.S. Patent Application Ser. No. 63/704,996 by Gan et al., entitled “RADIATION-HARDENED SEMICONDUCTOR SYSTEMS,” filed Oct. 8, 2024, which is assigned to the assignee hereof, and which is expressly incorporated by reference in its entirety herein.

### TECHNICAL FIELD

The following relates to one or more techniques for semiconductor systems, including radiation-hardened semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells. In some implementations, memory devices, among other semiconductor devices or systems, may operate in an environment in which the devices are exposed to radiation, which may impact operations (e.g., storage operations, processing operations) performed by the devices.

### BRIEF DESCRIPTION OF THE DRAWINGS

FIG. 1 shows an example of a system that supports radiation hardening for semiconductor systems in accordance with examples as disclosed herein.

FIG. 2 shows an example of a system that supports radiation hardening for semiconductor systems in accordance with examples as disclosed herein.

FIG. 3 shows an example of film configurations that support radiation hardening for semiconductor systems in accordance with examples as disclosed herein.

FIG. 4 shows a flowchart illustrating a method or methods that support radiation hardening for semiconductor systems in accordance with examples as disclosed herein.

### DETAILED DESCRIPTION

Electronic devices, such as semiconductor systems or electronic systems that include semiconductor components (e.g., semiconductor devices), may be affected by incident radiation, such as cosmic rays or neutron irradiation. In memory systems or processing systems, for example, such radiation may cause bit flips, which may lead to errors and potential data corruption (e.g., when a quantity of bit flips exceeds an error correction capability). Although electronic devices may be capable of correcting some errors caused by incident radiation (e.g., on memory circuitry, on processing circuitry, or on both), some advanced applications, like quantum computing, may be more susceptible to such bit flips, which may be more likely to exceed error correction capabilities. A vulnerability to incident radiation may hinder quantum computing operations, for example, resulting in faulty information and other operational errors, thereby compromising the reliability and performance of these advanced systems.

In accordance with examples as described herein, specialized shielding materials (e.g., radiation shielding films) may be implemented in electronic devices to protect circuitry of semiconductor components (e.g., memory components, processing components, or a combination thereof, semiconductor devices) from incident radiation. The shielding materials may include a combination of one or more film materials, such as organic polymer films, and one or more radiation shielding materials, such as boron compounds. The shielding materials can be arranged in various configurations, including single layer, multilayer, or filler-embedded orientations, which may balance film flexibility and radiation protection. By strategically placing these shielding layers on components of an electronic system (e.g., on semiconductor components), the system may effectively attenuate radiation incidence on circuitry of the system, thereby reducing the likelihood of radiation-induced errors and enhancing the overall reliability of the system.

In addition to applicability in memory systems as described herein, techniques for radiation hardening of memory systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing the effect of incidence radiation on memory systems, which may reduce error rates for high-performance systems, such as quantum computers, among other benefits.

Features of the disclosure are illustrated and described in the context of systems and architectures. Features of the disclosure are further illustrated and described in the context of film configurations and flowcharts.

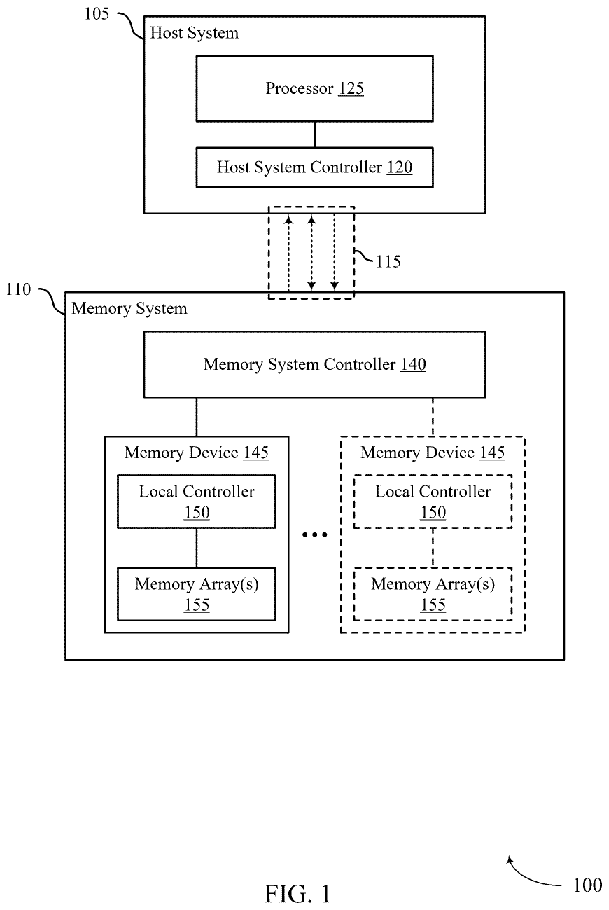

FIG. 1 shows an example of a system 100 that supports radiation hardening for semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

In some examples, the system 100 or a host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from a host system 105 (e.g., from a host system controller 120). For example, a memory system 110 (e.g., a memory system controller 140) may receive a write command indicating that the memory system 110 is to store data received from the host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support a memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of a system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a TCDRAM system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some examples, a system 100, or one or more components thereof (e.g., one or more semiconductor components of a system 100) may be affected by incident radiation, such as cosmic rays or neutron irradiation. In memory systems (e.g., a memory system 110, a memory system controller 140, a memory device 145) or processing systems (e.g., a host system 105, a processor 125, a host system controller 120), for example, such radiation may cause bit flips, which may lead to errors and potential data corruption (e.g., when a quantity of bit flips exceeds an error correction capability). Although components of a system 100 may be capable of correcting some errors caused by incident radiation (e.g., on memory circuitry, on processing circuitry, or on both), some advanced applications, like quantum computing, may be more susceptible to such bit flips, which may be more likely to exceed error correction capabilities. A vulnerability to incident radiation may hinder quantum computing operations, for example, resulting in faulty information and other operational errors, thereby compromising the reliability and performance of these advanced systems.

In accordance with examples as described herein, specialized shielding materials (e.g., radiation shielding films) may be implemented in one or more components of a system 100 to protect circuitry of semiconductor components (e.g., memory components, processing components, or a combination thereof) from incident radiation. The shielding materials may include a combination of one or more film materials, such as organic polymer films (e.g., polyethylene films, polydimethylsiloxane films), and one or more radiation shielding materials, such as boron compounds (e.g., ¹⁰B compounds, such as boron carbide materials, boron nitride materials, boron nitrite materials, or other compounds). The shielding materials can be arranged in various configurations, including single layer, multilayer, or filler-embedded orientations, which may balance film flexibility and radiation protection. By strategically placing these shielding layers on one or more components of a system 100 (e.g., on semiconductor components, of a host system 105, of a memory system 110, or of a combination thereof), the system 100 may effectively attenuate radiation incidence on circuitry of the system 100, thereby reducing the likelihood of radiation-induced errors and enhancing the overall reliability of the system 100.

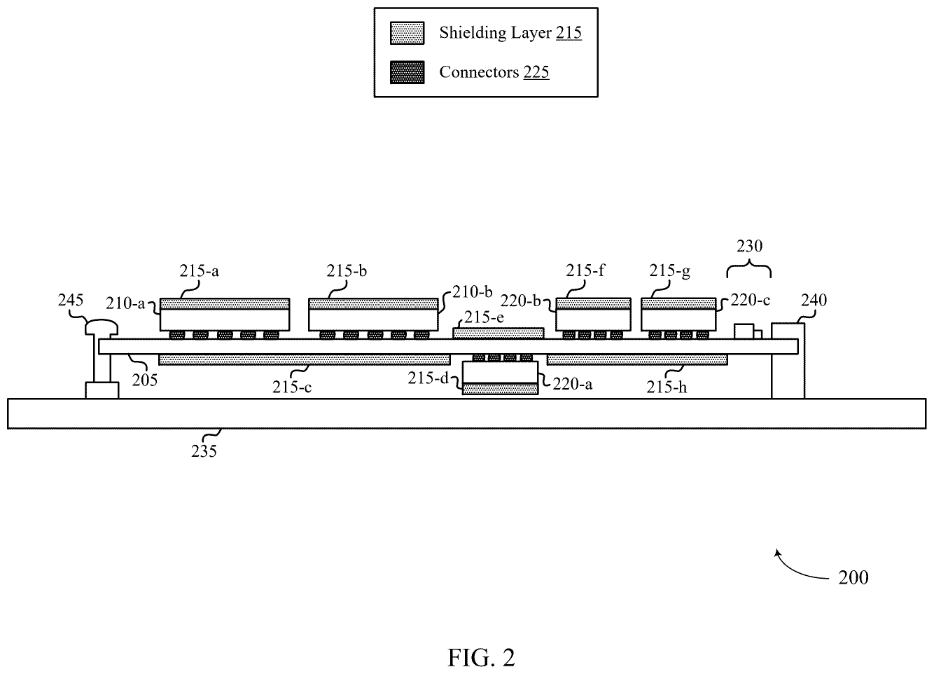

FIG. 2 shows an example of a system 200 that supports radiation hardening for semiconductor systems in accordance with examples as disclosed herein. The system 200 may be an example of a system 100 (e.g., including a host system 105 and one or more memory systems 110), or a component thereof (e.g., a host system 105, or a memory system 110, or a component thereof). A system 200 may illustrate various techniques that may be implemented to shield electronic components (e.g., semiconductor components) from incident radiation, as described herein.

In some examples, a system 200 may include a substrate 205. A substrate 205 may be an organic substrate, such as a printed circuit board (PCB), formed with layers of conductors and fiberglass or epoxy, for example. In some cases, the substrate 205 may be coupled with a board 235 (e.g., a gender board) via a board socket 240 and a screw 245 (e.g., a pin, a connector).

In some examples, a system 200 may include memory devices 210 (e.g., an example of a semiconductor component), which may be examples of the memory devices 145 (e.g., NAND chips, DRAM chips), among other implementations. For example, a system 200 may include a memory device 210-a and a memory device 210-b, which may be coupled with (e.g., soldered to, bonded with) the substrate 205. The memory devices 210 may include circuitry operable to access one or more memory arrays, and may be configured to other components of a system 200 via a substrate 205, such as via contacts 225, one or more electrical traces of the substrate 205, or both.

In some implementations, a respective shielding layer 215 (e.g., a polymer composite, a polymer adhesive film) may be coupled with (e.g., adhered to, taped to, bonded to) one or more memory devices 210 of a system 200. For example, a shielding layer 215-a may be adhered to a first surface of the memory device 210-a, and a shielding layer 215-b may be adhered to a first surface of the memory device 210-b, and so on. In some examples, a first surface of a memory device 210 may be or include a mold compound (e.g., formed on or around one or more semiconductor components of the memory device 210), and a shielding layer 215 may be bonded to the mold compound. A first surface of a memory device 210 may be opposite from a second surface of the memory device 210 that includes one or more contacts 225 (e.g., solder contacts, pads, connectors).

In some examples, an area of a shielding layer 215 (e.g., a bonding area) may be the same as, or relatively close to (e.g., within a tolerance, within a threshold amount) an overall area of the first surface of the corresponding memory device 210. In some other examples, the area of the shielding layer 215 may be larger than the overall area of the first surface of the corresponding memory device 210. In some examples, the shielding layer 215 may cover one or more edges (e.g., may wrap around one or more edges, may wrap toward a contact surface or substrate 205) of the corresponding memory device 210 (e.g., perpendicular to the first surface). Accordingly, the shielding layer 215 may be configured to shield the corresponding memory device 210 from radiation incidence from other directions.

In some examples, to shield a memory device 210 from radiation incidence on a respective second surface, one or more additional shielding layers 215 may be implemented. For example, the memory device 210-a may be coupled with a first surface of the substrate 205 (e.g., via contacts 225), and a shielding layer 215-c may be adhered to a second surface of the substrate 205 opposite the first surface to attenuate radiation incidence on circuitry the memory device 210-a from the second surface. In some examples, the shielding layer 215-c may be adhered to an area of the second surface of the substrate 205 that is the same (e.g., or relatively close) to an area of the memory device 210-a projected on the second surface. In some other examples, the shielding layer 215-c may have an area larger than the area of the memory device 210-a projected on the second surface. For example, the shielding layer 215-c may be configured to shield circuitry of both the memory device 210-a and the memory device 210-b from incident radiation, and may have an area that covers at least a projection of both the memory device 210-a and the memory device 210-b on the second surface, as shown. In some cases, the shielding layer 215-c may coexist with one or more electrical traces on the second surface of the substrate 205. For example, the shielding layer 215-c may be adhered over the electrical traces, and the shielding layer 215-c (e.g., at least a surface of the shielding layer 215-c, the adhesive, or both), or an outer surface of the substrate 205, or both may be non-conductive, thereby avoiding shorting of the electrical traces.

In some examples, one or more components 220 (e.g., processors, processor cores, processing chips, controller chips, an example of a semiconductor component) may be coupled with the substrate 205 (e.g., via one or more contacts 225). For example, a component 220 may be an example of a host system 105, a processor 125, a host system controller 120, or a memory system controller 140. In some examples, one or more components 220 may be positioned on the first surface of the substrate 205, one or more components 220 may be positioned on the second surface of the substrate 205, or both. For example, a component 220-a may be coupled with the second surface of the substrate 205, and a shielding layer 215-d may be adhered to the component 220-a. In some examples, a shielding layer 215-e may also be adhered to the first surface of the substrate 205 at an area opposite the position of the component 220-a. As such, the component 220-a may be shielded from incident radiation from either direction. Similarly, a shielding layer 215-f and a shielding layer 215-g may be adhered to a component 220-b and a component 220-c, respectively, that are coupled with the first surface of the substrate 205.

In some examples, a shielding layer 215-h may cover an area at the second surface of the substrate 205 corresponding to the component 220-b and the component 220-c, thereby shielding both the component 220-b and the component 220-c from incident radiation. In some cases, the shielding layer 215-h may coexist with one or more electrical traces on the second surface of the substrate 205. For example, the shielding layer 215-h may be adhered over the electrical traces, and the shielding layer 215-h (e.g., at least a surface of the shielding layer 215-c, the adhesive, or both) may be non-conductive, thereby avoiding shorting of the electrical traces.

In some examples, each of the shielding layers 215 on a same surface of the substrate 205 may have a common height (e.g., from the substrate 205). Such an arrangement may allow a common heat sink (not shown) to be placed above the shielding layers 215 to increase heat dissipation for multiple components coupled with the substrate 205 simultaneously. Additionally, or alternatively, shielding layers 215 may include one or more materials (e.g., thermally conductive adhesives, epoxy, silicone materials, acrylate materials) to act as a heatsink while also shielding circuitry from radiation.

Each of the shielding layers 215 may include one or more materials, such boron materials (e.g., ¹⁰B compounds, boron nitride, boron carbide, boron polymers) that may absorb, reflect, or otherwise stop radiation incidence from reaching circuitry of memory devices 210 or other components 220. In some examples, a shielding layer 215 may be bonded using an adhesive film (e.g., a polymer adhesive film) included in the shielding layer 215. For example, the adhesive film may be (e.g., temporarily) covered by a release film (e.g., a non-adhesive backing), which may be removed to adhere the shielding layer 215 to a component of the system 200. In some cases, a thickness of each shielding layer 215 may vary depending on space constraints of the system 200, and may be the same or different for each shielding layer 215 corresponding to different components. In some examples, the thickness of each shielding layer 215 may be in a range of 0.1 to 3 mm.

In some examples, the system 200 may include one or more components 230 that may not be shielded using shielding layers 215. In some cases, components 230 may be relatively smaller than other components of the system 200 such that incident radiation may be less likely to occur, or the components 230 may be less likely to experience errors if incident radiation is experienced.

The placement of memory devices 210 and components 220 on the example of a substrate 205 are exemplary, and different positioning may be used in accordance with the techniques as described herein. Additionally, or alternatively, some of the memory devices 210 shown may be replaced with components 220. The quantity of components of a system 200 may also be different, and the size or position of shielding layers 215 may be based on the positioning of other components. For example, a shielding layer 215 may be configured to shield multiple components of the system 200 (e.g., more than two) by covering a larger area of the substrate 205. Accordingly, by including the shielding layers 215, the system 200 may support reducing error rates by attenuating radiation incidence on circuitry of the system 200, thereby enhancing the overall stability and longevity of the system 200.

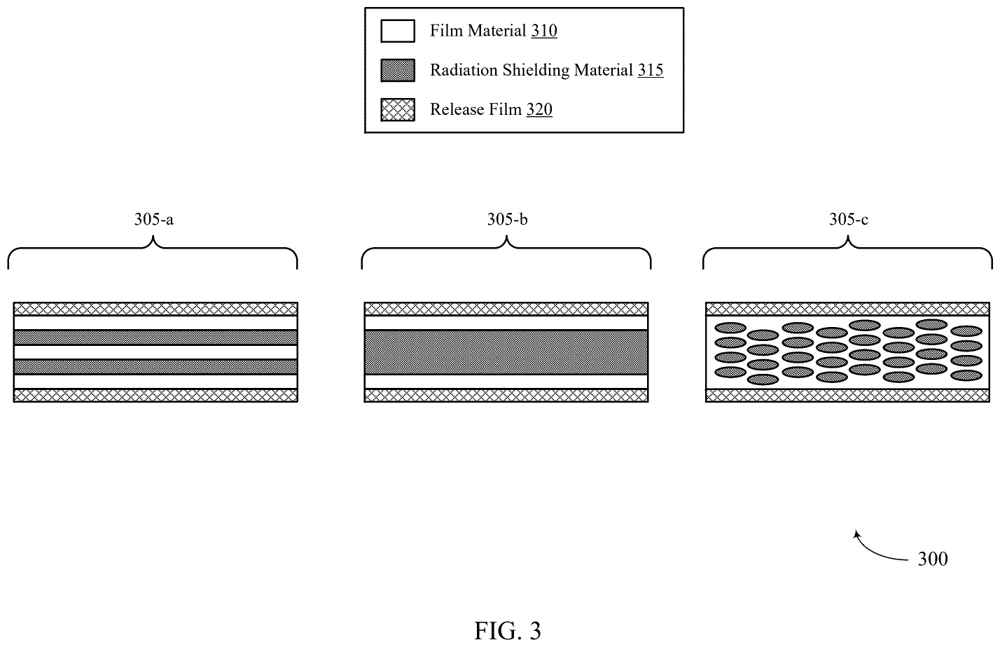

FIG. 3 shows an example of film configurations 300 that support radiation hardening for semiconductor systems in accordance with examples as disclosed herein. Each of the film configurations 300 may be implemented at a respective shielding layer 215, for example. The film configurations 300 may include various arrangements of film material 310 and radiation shielding material 315, which may each be configured to provide effective radiation attenuation for electronic components and may use different designs to balance flexibility and shielding efficiency.

In some examples, a film material 310 may serve as a primary substrate for a shielding layer 215. A film material 310 may include polydimethylsiloxane (PDMS), high-density polyethylene (HDPE), an organic polymer film, other polymer materials, or a combination thereof. In some examples, a composition of a film material 310 may be selected to achieve a flexibility, durability, or compatibility with the radiation shielding materials 315. A film material 310 can be implemented in various thicknesses, which may be based on different applications and packaging constraints within a system 100 or a system 200.

In some examples, a radiation shielding material 315 may be embedded within or layered with a film material 310 of a shielding layer 215 to attenuate radiation incidence on circuitry of an electronic component. In some cases, a radiation shielding material 315 may include boron (e.g., a ¹⁰B isotope), such as a boron compound (e.g., boron nitride, boron carbide), among other radiation-attenuating material(s). For example, a radiation shielding material 315 may be selected based on a neutron absorption cross-section, which may reduce the incidence of cosmic rays and other forms of radiation that on circuitry of an electronic component, thereby preventing bit flips and other errors in processing or memory systems. In some cases, a radiation shielding material 315 may include one or more filler (e.g., sheet) materials (e.g., in addition to boron compounds), and a filler materials may be at a concentration between 30 -80%, for example.

The configuration 305-a illustrates an example of a multilayer configuration. For example, one or more layers of the film material 310 and one or more layers of the radiation shielding material 315 may be interleaved, which may achieve a threshold radiation attenuation capability by increasing the overall thickness of the shielding material 315, while supporting relatively high flexibility of a shielding layer 215 due to the interleaved layers of the film material 310. In some examples, a quantity or size of the layers of the film material 310, the radiation shielding material 315, or both, may be selected based on a radiation protection level, a flexibility level, an overall thickness constraint, or a combination thereof.

The configuration 305-b illustrates an example of a single layer configuration (e.g., single radiation shielding material 315 layer). For example, the configuration 305-b may include a single layer of the radiation shielding material 315 embedded between at least two layers of the film material 310. In some examples, the configuration 305-b may increase radiation protection and rigidity of a shielding layer 215 (e.g., compared with the configuration 305-a). In some examples, the configuration 305-b may be selected to provide additional structure support (e.g., stiffness, strength) to a component upon which a shielding layer 215 is adhered.

The configuration 305-c illustrates an example of a distributed configuration (e.g., a dispersed configuration, with one or more portions of the radiation shielding material 315 embedded within a film material 310). In this configuration, the radiation shielding material 315 may be distributed in discrete portions throughout the film material 310, providing localized areas of enhanced radiation protection. In some cases, the configuration 305-c may be used for targeting specific regions of an electronic component that are more susceptible to radiation-induced errors (e.g., by varying a positioning or concentration of the one or more pockets of the radiation shielding material 315), while also enhancing the flexibility of a shielding layer 215.

In some examples, each of the configuration 305-a, the configuration 305-b, and the configuration 305-c may include one or more release films 320 (e.g., on one side of a shielding layer 215, on both sides of a shielding layer 215). A release film 320 may be a temporary layer that covers an adhesive side of the film material 310 before application to component of a system 100 or a system 200. For example, a release film 320 may protect an adhesive surface during handling and storage, ensuring that the film material 310 can be securely adhered to a component or a substrate. When a shielding layer 215 is ready to be applied, the release film 320 may be removed, exposing the adhesive layer for bonding with components or the substrate.

Accordingly, shielding layers 215 implemented in a system 100 or a system 200 may be configured in accordance with one or more film configurations 300 to achieve different flexibility and radiation shielding parameters, which may be based on different use cases for one or more components of a system 100 or a system 200 (e.g., quantum computing applications).

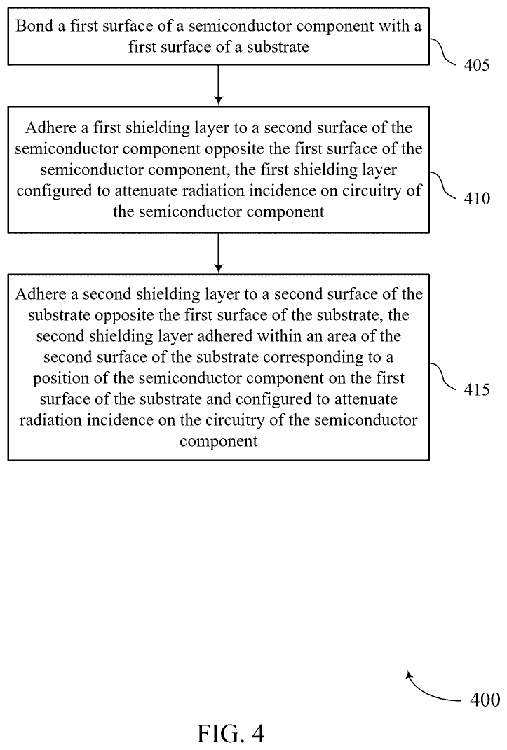

FIG. 4 shows a flowchart illustrating a method 400 that supports radiation hardening for semiconductor systems in accordance with examples as disclosed herein. The operations of method 400 may be implemented by a manufacturing system or its components as described herein. For example, operations of method 400 may be performed by a manufacturing system as described with reference to FIGS. 1 through 3. In some examples, a manufacturing system may execute a set of instructions to control the functional elements of the device to perform the described functions. Additionally, or alternatively, the manufacturing system may perform aspects of the described functions using special-purpose hardware.

At 405, the method may include bonding a first surface of a semiconductor component (e.g., a memory device, such as a memory device 145 or a memory device 210, a processing device, such as a processor 125, among other components or combinations of components of a system 100) with a first surface of a substrate (e.g., a substrate 205).

At 410, the method may include adhering a first shielding layer (e.g., a shielding layer 215) to a second surface of the semiconductor component opposite the first surface of the semiconductor component, the first shielding layer configured to attenuate radiation incidence on circuitry of the semiconductor component.

At 415, the method may include adhering a second shielding layer (e.g., another shielding layer 215) to a second surface of the substrate opposite the first surface of the substrate, the second shielding layer adhered within an area of the second surface of the substrate corresponding to a position of the semiconductor component on the first surface of the substrate and configured to attenuate radiation incidence on the circuitry of the semiconductor component.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for bonding a first surface of a semiconductor component with a first surface of a substrate; adhering a first shielding layer to a second surface of the semiconductor component opposite the first surface of the semiconductor component, the first shielding layer configured to attenuate radiation incidence on circuitry of the semiconductor component; and adhering a second shielding layer to a second surface of the substrate opposite the first surface of the substrate, the second shielding layer adhered within an area of the second surface of the substrate corresponding to a position of the semiconductor component on the first surface of the substrate and configured to attenuate radiation incidence on the circuitry of the semiconductor component.
Aspect 2: The method, apparatus, or non-transitory computer-readable medium of aspect 1, where each of the first shielding layer and the second shielding layer include a film material and a radiation shielding material; the film material includes polydimethylsiloxane, high-density polyethylene, or both; and the radiation shielding material includes boron nitride, boron carbide, or both.
Aspect 3: The method, apparatus, or non-transitory computer-readable medium of any of aspects 1 through 2, where the semiconductor component is a memory device comprising one or more memory arrays and circuitry operable to access the one or more memory arrays.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 4: An electronic system (e.g., a system 100, a system 200), including: a substrate (e.g., a substrate 205); a semiconductor component (e.g., a memory device 145, a memory device 210, a component 220) coupled with a first surface of the substrate; a first shielding layer (e.g., a shielding layer 215) adhered to a first surface of the semiconductor component opposite the substrate, the first shielding layer configured to attenuate radiation incidence on circuitry of the semiconductor component; and a second shielding layer (e.g., a shielding layer 215) adhered to a second surface of the substrate opposite the first surface of the substrate, the second shielding layer located opposite the semiconductor component and configured to attenuate radiation incidence on the circuitry of the semiconductor component.
Aspect 5: The electronic system of aspect 4, where the first shielding layer, the second shielding layer, or both include a respective film material (e.g., one or more film materials 310) and a respective radiation shielding material (e.g., one or more radiation shielding materials 315).
Aspect 6: The electronic system of aspect 5, where the respective radiation shielding material of the first shielding layer, the second shielding layer, or both include boron nitride, boron carbide, or both (e.g., a portion of ¹⁰B, a ¹⁰B compound).
Aspect 7: The electronic system of any of aspects 5 through 6, where the respective film material of the first shielding layer, the second shielding layer, or both include polydimethylsiloxane, high-density polyethylene, or both.
Aspect 8: The electronic system of any of aspects 5 through 7, where the first shielding layer, the second shielding layer, or both include: a first layer of the respective film material; a second layer of the respective film material; and a contiguous layer of the respective radiation shielding material between the first layer of the respective film material and the second layer of the respective film material (e.g., in accordance with a configuration 305-b).
Aspect 9: The electronic system of any of aspects 5 through 8, where the first shielding layer, the second shielding layer, or both include: a plurality of layers of the respective film material; and a plurality of layers of the respective radiation shielding material interleaved between the plurality of layers of the respective film material (e.g., in accordance with a configuration 305-a) Aspect 10: The electronic system of any of aspects 5 through 9, where the first shielding layer, the second shielding layer, or both include: a layer of the respective film material; and a plurality of portions of the respective radiation shielding material embedded within the layer of the respective film material (e.g., in accordance with a configuration 305-c)
Aspect 11: The electronic system of any of aspects 4 through 10, further including: a second semiconductor component coupled with the first surface of the substrate; and a third shielding layer adhered to a first surface of the second semiconductor component opposite the substrate, the third shielding layer configured to attenuate radiation incidence on circuitry of the second semiconductor component.
Aspect 12: The electronic system of aspect 11, where the second shielding layer is further located opposite the second semiconductor component and configured to attenuate radiation incidence on the circuitry of the second semiconductor component.
Aspect 13: The electronic system of any of aspects 4 through 12, further including: a second semiconductor component (e.g., of a host system 105, of a processor 125, of a host system controller 120, of a memory system controller 140) coupled with one of the first surface of the substrate or the second surface of the substrate, the second semiconductor component including circuitry operable to access one or more memory arrays of the semiconductor component; and a fourth shielding material adhered to a surface of the second semiconductor component opposite the substrate, the fourth shielding material located opposite the second semiconductor component and configured to attenuate radiation incidence on the circuitry of the second semiconductor component.
Aspect 14: The electronic system of aspect 13, further including: a fifth shielding material adhered to the other of the first surface of the substrate or the second surface of the substrate, the fourth shielding material configured to attenuate radiation incidence on the circuitry of the second semiconductor component.
Aspect 15: The electronic system of any of aspects 4 through 14, where the first shielding layer wraps over one or more edges of the semiconductor component.
Aspect 16: The electronic system of any of aspects 4 through 15, wherein the semiconductor component is a memory device comprising one or more memory arrays and circuitry operable to access the one or more memory arrays.

An apparatus is described. The following provides an overview of aspects of the apparatus as described herein:
Aspect 17: A memory device, including: a semiconductor component (e.g., of a memory system 110, of a memory device 145, or of a component thereof) including one or more memory arrays and circuitry operable to access the one or more memory arrays; a mold compound material formed over the semiconductor component; and a shielding layer adhered to a first surface of the mold compound material opposite a second surface having one or more contacts of the memory device, the shielding layer configured to attenuate radiation incidence on the semiconductor component.
Aspect 18: The memory device of aspect 17, where the shielding layer includes a film material and a radiation shielding material.
Aspect 19: The memory device of aspect 18, where the radiation shielding material includes boron nitride, boron carbide, or both.
Aspect 20: The memory device of any of aspects 18 through 19, where the film material includes polydimethylsiloxane, high-density polyethylene, or both.
Aspect 21: The memory device of any of aspects 18 through 20, where the shielding layer includes: a first layer of the film material; a second layer of the film material; and a contiguous layer of the radiation shielding material between the first layer of the film material and the second layer of the film material.
Aspect 22: The memory device of any of aspects 18 through 21, where the shielding layer includes: a plurality of layers of the film material; and a plurality of layers of the radiation shielding material interleaved between the plurality of layers of the film material.
Aspect 23: The memory device of any of aspects 18 through 22, where the shielding layer includes: a layer of the film material; and a plurality of portions of the radiation shielding material embedded within the layer of the film material.
Aspect 24: The memory device of any of aspects 18 through 23, where the shielding layer wraps over one or more edges of the mold compound material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An electronic system, comprising:
a substrate;
a semiconductor component coupled with a first surface of the substrate;
a first shielding layer adhered to a first surface of the semiconductor component opposite the substrate, the first shielding layer configured to attenuate radiation incidence on circuitry of the semiconductor component; and
a second shielding layer adhered to a second surface of the substrate opposite the first surface of the substrate, the second shielding layer located opposite the semiconductor component and configured to attenuate radiation incidence on the circuitry of the semiconductor component.

2. The electronic system of claim 1, wherein the first shielding layer, the second shielding layer, or both comprise a respective film material and a respective radiation shielding material.

3. The electronic system of claim 2, wherein the respective radiation shielding material of the first shielding layer, the second shielding layer, or both comprise boron nitride, boron carbide, or both.

4. The electronic system of claim 2, wherein the respective film material of the first shielding layer, the second shielding layer, or both comprise polydimethylsiloxane, high-density polyethylene, or both.

5. The electronic system of claim 2, wherein the first shielding layer, the second shielding layer, or both comprise:
a first layer of the respective film material;
a second layer of the respective film material; and
a contiguous layer of the respective radiation shielding material between the first layer of the respective film material and the second layer of the respective film material.

6. The electronic system of claim 2, wherein the first shielding layer, the second shielding layer, or both comprise:
a plurality of layers of the respective film material; and
a plurality of layers of the respective radiation shielding material interleaved between the plurality of layers of the respective film material.

7. The electronic system of claim 2, wherein the first shielding layer, the second shielding layer, or both comprise:
a layer of the respective film material; and
a plurality of portions of the respective radiation shielding material embedded within the layer of the respective film material.

8. The electronic system of claim 1, further comprising:
a second semiconductor component coupled with the first surface of the substrate; and
a third shielding layer adhered to a first surface of the second semiconductor component opposite the substrate, the third shielding layer configured to attenuate radiation incidence on circuitry of the second semiconductor component.

9. The electronic system of claim 8, wherein the second shielding layer is further located opposite the second semiconductor component and configured to attenuate radiation incidence on the circuitry of the second semiconductor component.

10. The electronic system of claim 1, further comprising:
a second semiconductor component coupled with one of the first surface of the substrate or the second surface of the substrate, the semiconductor component comprising circuitry operable to access one or more memory arrays of the semiconductor component; and
a fourth shielding material adhered to a surface of the second semiconductor component opposite the substrate, the fourth shielding material located opposite the second semiconductor component and configured to attenuate radiation incidence on the circuitry of the second semiconductor component.

11. The electronic system of claim 10, further comprising:
a fifth shielding material adhered to the other of the first surface of the substrate or the second surface of the substrate, the fourth shielding material configured to attenuate radiation incidence on the circuitry of the second semiconductor component.

12. The electronic system of claim 1, wherein the first shielding layer wraps over one or more edges of the semiconductor component.

13. The electronic system of claim 1, wherein the semiconductor component is a memory device comprising one or more memory arrays and circuitry operable to access the one or more memory arrays.

14. A memory device, comprising:
a semiconductor component comprising one or more memory arrays and circuitry operable to access the one or more memory arrays;
a mold compound material formed over the semiconductor component; and
a shielding layer adhered to a first surface of the mold compound material opposite a second surface having one or more contacts of the memory device, the shielding layer configured to attenuate radiation incidence on the semiconductor component.

15. The memory device of claim 14, wherein the shielding layer comprises a film material and a radiation shielding material.

16. The memory device of claim 15, wherein the radiation shielding material comprises boron nitride, boron carbide, or both.

17. The memory device of claim 15, wherein the film material comprises polydimethylsiloxane, high-density polyethylene, or both.

18. The memory device of claim 15, wherein the shielding layer comprises:
a first layer of the film material;
a second layer of the film material; and
a contiguous layer of the radiation shielding material between the first layer of the film material and the second layer of the film material.

19. The memory device of claim 15, wherein the shielding layer comprises:
a plurality of layers of the film material; and
a plurality of layers of the radiation shielding material interleaved between the plurality of layers of the film material.

20. The memory device of claim 15, wherein the shielding layer comprises:
a layer of the film material; and
a plurality of portions of the radiation shielding material embedded within the layer of the film material.

21. The memory device of claim 14, wherein the shielding layer wraps over one or more edges of the mold compound material.

22. A method, comprising:
bonding a first surface of a semiconductor component with a first surface of a substrate;
adhering a first shielding layer to a second surface of the semiconductor component opposite the first surface of the semiconductor component, the first shielding layer configured to attenuate radiation incidence on circuitry of the semiconductor component; and
adhering a second shielding layer to a second surface of the substrate opposite the first surface of the substrate, the second shielding layer adhered within an area of the second surface of the substrate corresponding to a position of the semiconductor component on the first surface of the substrate and configured to attenuate radiation incidence on the circuitry of the semiconductor component.

23. The method of claim 22, wherein:
each of the first shielding layer and the second shielding layer comprise a film material and a radiation shielding material;
the film material comprises polydimethylsiloxane, high-density polyethylene, or both; and
the radiation shielding material comprises boron nitride, boron carbide, or both.

24. The method of claim 22, wherein the semiconductor component is a memory device comprising one or more memory arrays and circuitry operable to access the one or more memory arrays.
